(19) United States
(12) Patent Application Publication
(10) Pub. No.: US 2009/0102038 A1
(43) Pub. Date: Apr. 23, 2009

(54) CHIP SCALE STACKED DIE PACKAGE

(75) Inventors: SIMON J.S. MCELREA, Scotts Valley, CA (US); Marc E. Robinson, San Jose, CA (US); Lawrence Douglas Andrews, JR., Los Gatos, CA (US); Terrence Caskey, Santa Cruz, CA (US); Scott McGrath, Scotts Valley, CA (US); Yong Du, Cupertino, CA (US); Al Vindasius, Saratoga, CA (US)

Correspondence Address: HAYNES BEFFEL & WOLFELD LLP, P O BOX 366, HALF MOON BAY, CA, 94019, US

(73) Assignee: VERTICAL CIRCUITS, INC., Scotts Valley, CA (US)

(21) Appl. No.: 12/251,624

(22) Filed: Oct. 15, 2008

Related U.S. Application Data
(60) Provisional application No. 60/981,085, filed on Oct. 18, 2007.

(51) Int. Cl. H01L 23/488; H01L 21/02

(52) U.S. Cl. 257/686; 438/109; 257/E23.023; 257/E21.002

(57) ABSTRACT

A die prepared for stacking in a chip scale stacked die assembly, having interconnect sites in an area inward from a die edge and interconnect pads near at least one die edge. Second-level interconnection of the stacked die assembly can be made by way of connections between a first die in the assembly and circuitry on a support; and interconnection between die in the stack can be made by way of connection of z-interconnects with bonds pads in the die attach side of the support near or at one or more die edges. Methods for preparing the die include processes carried out to an advanced stage at the wafer level or at the die array level.

### CROSS-REFERENCE TO RELATED APPLICATIONS

This application claims priority from M. Robinson et al. U.S. Provisional Application No. 60/981,085, titled “Chip scale stacked die package”, which was filed Oct. 18, 2007, and which is hereby incorporated by reference herein.

### BACKGROUND

This invention relates to stackable integrated circuit devices suited for vertical electrical interconnection, and to chip scale stacked die packages.

Semiconductor die are provided with interconnect sites (pads) in the circuit side (active side or front side) for electrical connection of the circuitry on the die with circuitry on other die, or with circuitry in a device in which the electronic functionality of the die is used. The die pads in the die as provided may be arranged near one or more die edges (“peripheral pads”, “peripheral pad die”) or in one or more rows along a centerline of the die (“center pads”, “center pad die”), for example. Die may be stacked one over another; a die in a stack may be electrically connected to another die in the stack (herein, “z-interconnect”) directly by, for example, wire bonds connecting pads on one die with pads on another die; or, a die may be mounted with another die face-to-face (so that the circuit sides of the respective die face toward one another and respective pads are aligned to oppose one another) and interconnected (“z-interconnect”) by, for example, bumps or balls connecting opposed pads. In environments employing electronically dense die, where the die may have a large number of pads, and particularly where the pads are small and arranged close together, it may be impractical to directly connect the die to underlying circuitry in the apparatus (such as to a printed circuit board, for example a motherboard), and in such situations the die may be mounted on, and electrically connected with circuitry in, a substrate or leadframe to form a package. The circuitry on the substrate, or the shape of the leadframe, typically provides less closely arranged attachment sites for connection of the package to the underlying circuitry. A conventional substrate typically has one or more (usually two or more) layers of electrically conductive material (such as a metallization, for example) patterned to form conductive traces. A substrate typically has bond pads on conductive traces in a die mount side for electrical interconnection of the die. The die may be mounted on the substrate with the back side of the die facing the substrate, and the die may be electrically connected by wire bonds (“wire bond interconnect”) between pads on the die and bond pads on the substrate. Or, the die may be mounted with the active side facing the substrate and pads on the die aligned to oppose corresponding bond sites on the substrate, and the die electrically connected by bumps or balls connected to the opposed pads and bond sites (“flip chip interconnection”). The package substrate typically also has conductive traces on the side opposite the die mount side (the “land side”) with bond sites on the land side exposed for interconnection of the package with underlying circuitry (“second-level interconnect”) by, for example, solder balls or wire bonds. Typically the traces on the die attach side are connected as appropriate by way of vias through the substrate dielectric to traces on the land side. In the resulting package the circuitry on the die makes electrical connection with the underlying circuitry by way of the bond pads on the traces in the die attach side of the substrate, then by way of the vias to the traces on the land side of the substrate, then by way of the traces on the land side to the second-level interconnect sites. For complex electronic circuitry the substrate may have additional layers of patterned conductive material. The land side interconnect sites are typically situated in an array, and such a substrate may be referred to as a land grid array (“LGA”) substrate or, if provided with second-level interconnect solder balls, as a ball grid array (“BGA”) substrate.

In a “chip scale package”, the overall footprint of the package is made as small as practicable and, ideally, the overall package footprint is nearly as small as the footprint of the largest die in the package. As a practical matter, interconnection of the die to the substrate may occupy some area of the substrate adjacent one or more edges of the die (particularly where the die is wire bonded to the substrate, for example).

U.S. Pat. No. 7,245,021 describes an assembly of stacked vertically interconnected semiconductor die. Interconnect sites on the die as provided are rerouted to die pads arranged at one or more die edges, and short flexible bond wires or ribbons are attached to the die pads and protrude beyond the die edges. Interconnection of the die in the stack (z-interconnect) is made by way of an electrically conductive polymer, or epoxy, filaments or lines contacting the protruding wires or ribbons at the sides of the die stack. U.S. Pat. No. 7,215,018 describes a stacked die package having a stacked vertically interconnected semiconductor die assembly as in U.S. Pat. No. 7,245,021 mounted on and electrically connected to a ball grid array (“BGA”) or land grid array (“LGA”) substrate. Electrical connection (second-level interconnect) in the package is made by contact of the z-interconnects with bond pads in the die attach side of the substrate.

Substrates can be costly to make, particularly where more than two layers of patterned conductive material are employed. A substrate has a finite thickness, which adds to the overall thickness of the package.

### SUMMARY

In general the invention features vertically interconnected stacked semiconductor die assemblies configured for second-level attachment directly to underlying circuitry, without a need for a separate substrate interposed for interconnection of the die circuitry to the underlying circuitry; and semiconductor die configured for use in such assemblies. Also in general the invention features methods for preparing die and for stacking the prepared die to form the assemblies.

The second-level interconnection of the stack to underlying circuitry is made by way of a plurality of connections (in some embodiments the connections are arranged in an array) in the shadow of the die stack between a first die in the assembly and circuitry on a support; and in some embodiments second-level interconnect is additionally made by way of contact of z-interconnects with bond pads near or at one or more die edges in the die attach side of the support. The first die (at least) in the stack optionally includes one or more rerouting traces from the pads in the die as provided to the interconnect pads. In such embodiments the second-level interconnection may be made at second-level interconnect sites on the rerouting traces.

In one general aspect the invention features a stacked semiconductor die assembly including a second die mounted on a first die, in which the front side of the second die faces the back side of the first die, and the front side of the first die includes z-interconnect pads situated near at least one die edge, and second-level interconnect sites situated in an area (and in some embodiments in an array) inwardly from a die edge.

In some embodiments the stacked die assembly includes at least one additional die stacked over the second die; that is, the assembly may include three or more die (as many as may be desired).

In some embodiments both the first and the second die include z-interconnect pads situated near at least one die edge. In some such embodiments interconnect terminals are attached to the z-interconnect pads and project to the die edge or beyond the die edge (“off-die” terminals); in some such embodiments the interconnect terminal may include a ribbon bond, or a tab bond, or a deposit of solder paste, or a deposit of an electrically conductive polymer, for example.

In some embodiments both the first and the second die additionally include second-level interconnect sites situated in an area (and in some embodiments in an array) inwardly from a die edge.

In some embodiments the first die has electrically conductive second-level interconnect balls attached to second-level interconnect sites in the area inboard from the die edge. In some embodiments the second die (and additional die, if present) also has standoff balls attached to the second-level interconnect sites. The material of the standoff balls may be electrically conductive; or the material of the standoff balls may be electrically nonconductive. Where the standoff balls are electrically conductive the first die (or the second and addition die, where present) may include an electrical insulator situated between the back side of the first die and the standoff balls on the second die, and between the backside of the second die and additional die, where present, and the standoff balls on any die stacked over.

In other embodiments no standoffs are provided in the die footprint of the second die (or in one or more of the additional die, if present).

In another general aspect the invention features methods for preparing semiconductor die for use in vertically interconnected stacked semiconductor die assemblies configured for attachment directly to underlying circuitry. Some steps, at least, of the methods are carried out at the wafer processing or at the die array level.

In some embodiments the method includes providing a semiconductor wafer having electronic circuitry formed in die regions of an active side thereof, and including a first dielectric layer having openings exposing die pads connected to the electronic circuitry at the surface of the wafer; forming electrically conductive rerouting traces over the first dielectric layer, electrically connected to the die pads; optionally forming a second dielectric layer over the rerouting traces; forming openings through the second dielectric layer (where present) exposing sites on the rerouting traces in an area inward from a die edge and exposing peripheral die pads. Certain of the rerouting procedures may be omitted if the wafer as provided has sites and peripheral pads in suitable locations. In some embodiments the method may further include forming standoff bumps on at least selected ones of the exposed inward sites; and optionally forming interconnect terminals on at least selected ones of the peripheral die pads.

In some embodiments forming the standoff bumps includes forming or depositing bumps of an electrically conductive material on at least selected ones of the exposed sites; the electrically conductive material may include a stud bump, for example, or a solder paste, for example, or a curable electrically conductive material such as, for example, a curable electrically conductive polymer, for example. In some embodiments forming the standoff bumps includes forming or depositing bumps of an electrically insulative material on at least selected ones of the exposed sites; the electrically insulative material may include, for example, a glass or an organic polymer; and the bumps may have a spheroidal shape, for example.

In some embodiments the circuitry on the wafer may be tested at one or more stages, for example: following forming openings through the second dielectric layer, or (particularly where the material of the standoff bumps is electrically conductive) following forming the standoff bumps; or following forming the interconnect terminals.

In some embodiments the method further includes singulating die from the wafer; in some embodiments singulating is carried out following forming openings through the second dielectric layer, or following forming the standoff bumps; in some embodiments singulating is carried out prior to forming the interconnect terminals.

In some embodiments, die sidewalls are formed in an unthinned wafer by forming trenches in the front side of the wafer to a depth at least equal to the die thickness; in such embodiments thinning the wafer, for example by backgrinding, results in singulated die (wafer cutting before thinning; so-called “dice before grind”). In other embodiments the wafer is thinned before cutting thru to singulate the die (so-called “dice after grind”). Optionally a conformal electrically insulative coating, for example of a polymer such as a parylene, may be applied to the front side and die sidewalls following formation of the trenches (at the wafer level of processing), or following singulation (at the die array level of processing).

In some embodiments the method further includes forming a die attach adhesive layer over the second dielectric layer and the standoff bumps. In some embodiments the method further includes forming a die attach adhesive layer over the back side of a die to which a second or additional die is to me mounted. Forming the die attach adhesive layer may be carried out prior to, or in some embodiments following, forming the interconnect terminals.

In another general aspect the invention features methods for making a stacked semiconductor die assembly, by mounting a second die prepared as described above upon a first die prepared as described above, to make a stacked die assembly or an array of stacked die assemblies. For a die assembly having more than two die stacked one over another, the method further includes mounting at least one additional die over the second die. Mounting may be carried out at the wafer level, or at the die array level, or at the singulated die level; that is, mounting may be carried out prior to or, in some embodiments following, die singulation. In some embodiments the second and additional die may be mounted serially one over another; in other embodiments two or more of the second and additional die may be stacked to form a subassembly, and thereafter the subassembly (or subassemblies) may be mounted one over another to form the stacked die assembly.

In some embodiments the method further includes forming z-interconnection of at least selected ones of the interconnect terminals; in some embodiments forming z-interconnection includes forming lines or stripes of an electrically conductive polymer in contact with interconnect terminals to be connected.

In various embodiments, stacked die chip scale assemblies are provided, having second-level interconnects provided for on a first die (at a “lower” side of the assembly). The second-level interconnection of the assembly to underlying circuitry in a support (such as a substrate, or leadframe, or printed circuit board, for example) may be made by way of interconnect balls or bumps attached to sites (lands) in an area (and in some embodiments in an array) inward from a die edge, on the active side of the first die, and connected to bond pads in the underlying circuitry. In various embodiments die prepared for use in the assemblies are provided with second-level interconnect sites and with z-interconnect pads near one or more die edges. The arrangement of sites and pads in prepared die may be present in the wafer as provided, or may be made by applying rerouting circuitry. In various embodiments Z-interconnection of die to other die in the stack, or to the underlying circuitry, is made by way of peripheral interconnects at one or more stack faces. In various embodiments the peripheral interconnects contact the pads directly (by incursion into a space between adjacent die in the stack); or they contact interconnect terminals which are connected to the pads. The interconnect terminals may include a bump or spot of electrically conductive material formed on the pad. Or, the interconnect terminals may be “off-die” terminals, such as for example wires or ribbons attached to the pads and extending beyond the die edge; or they may be traces of conductive material formed in contact with the pads and extending to a die edge; or extending around a die edge, which may in some embodiments be chamfered or rounded; or extending around a die edge to the adjacent die sidewall.

In any of the embodiments, the second die (and additional die, where present) may be all the same size and functionality, and may be the same size and may have the same functionality of the first die; or, one or more of the various die may be of different sizes and/or may have different functionalities.

And in various embodiments die are prepared for assembly into such stacked die chip scale assemblies in procedures carried out to late stages at the wafer level or at the die array level of processing.

The assemblies according to the invention can be used for building computers, telecommunications equipment, and consumer and industrial electronics devices.

### BRIEF DESCRIPTION OF THE DRAWINGS

FIG. 1A is a diagrammatic sketch in a plan view showing the circuit side of a one-half portion of a semiconductor wafer.

FIG. 1B is a diagrammatic sketch in a plan view showing a portion of the wafer of FIG. 1A including the area of an integrated circuit chip.

FIG. 2A is a diagrammatic sketch in a plan view showing a portion of the wafer of IA including the area of an integrated circuit chip as in FIG. 1B, enlarged.

FIG. 2B is a diagrammatic sketch in a sectional view as indicated at 2B-2B, including an integrated circuit chip.

FIGS. 2C through 2H are diagrammatic sketches in sectional view as in FIG. 2B, showing stages in a process for making a stackable integrated circuit chip according to an embodiment of the invention.

FIG. 3 is a diagrammatic sketch in sectional view showing a stackable integrated circuit chip according to an embodiment of the invention.

FIGS. 4A-4D are diagrammatic sketches in sectional view as in FIG. 2B, showing stages in a process for making a stacked integrated circuit chip assembly according to an embodiment of the invention.

FIGS. 5A through 5F are diagrammatic sketches in elevational view showing stages in a process for making a stackable integrated circuit chip according to an embodiment of the invention.

FIG. 6 is a diagrammatic sketch in a plan view showing a stage in a process for making a stackable integrated circuit chip according to an embodiment of the invention, as shown for example in a diagrammatic sectional view in FIG. 2E.

FIG. 7 is a diagrammatic sketch in a plan view showing a stackable integrated circuit chip according to an embodiment of the invention, as shown for example in a diagrammatic sectional view in FIG. 3.

FIG. 8 is a diagrammatic sketch in a plan view showing a stage in a process for making a stackable integrated circuit chip according to an embodiment of the invention, as shown for example in a diagrammatic sectional view in FIG. 5A.

FIG. 9 is a diagrammatic sketch in a plan view showing a stackable integrated circuit chip according to an embodiment of the invention, as shown for example in a diagrammatic sectional view in FIG. 5F.

FIGS. 10A-10B are diagrammatic sketches in sectional view showing stages in a process for making an assembly of stacked integrated circuit chips, generally as shown in FIG. 5F, according to an embodiment of the invention.

FIG. 11 is a diagrammatic sketch in sectional view showing an assembly including a first stackable integrated circuit chip generally as shown in FIG. 3, stacked with a second similar chip lacking ball interconnects and interconnected by peripheral z-interconnects.

FIG. 12 is a diagrammatic sketch in sectional view showing an assembly including a first stackable integrated circuit chip generally as shown in FIG. 5F, stacked with a second similar chip, generally as shown in FIG. 5E, lacking ball interconnects and interconnected by peripheral z-interconnects.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs. Also for clarity of presentation certain features are not shown in the FIGs., where not necessary for an understanding of the invention.

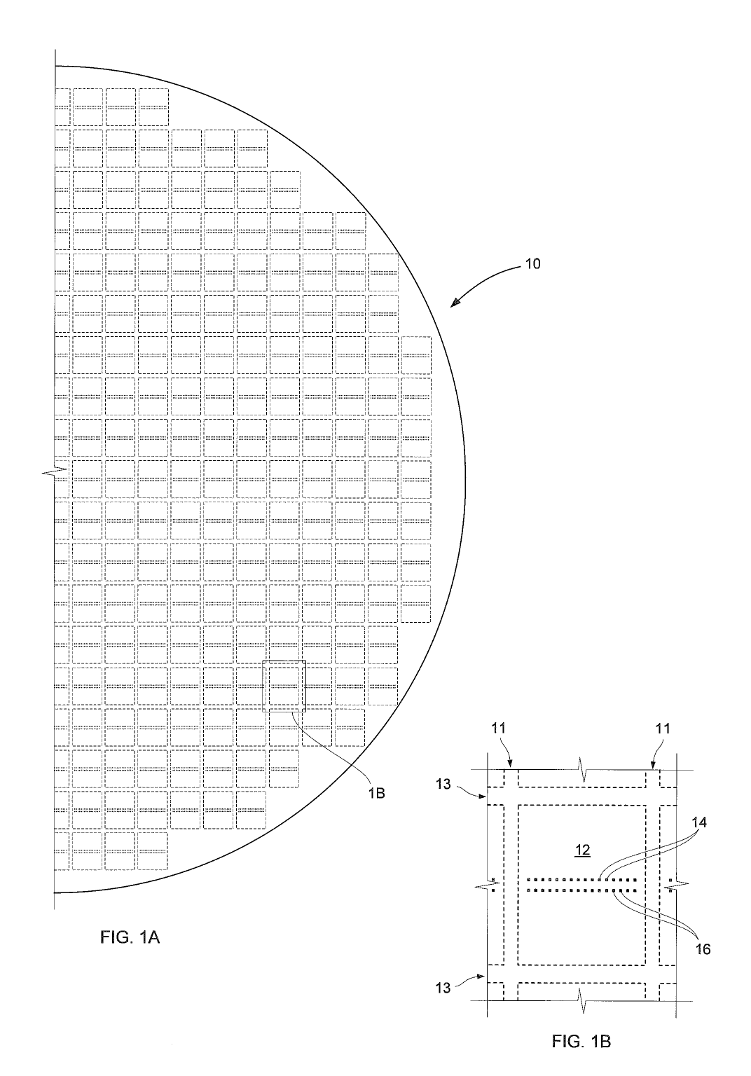

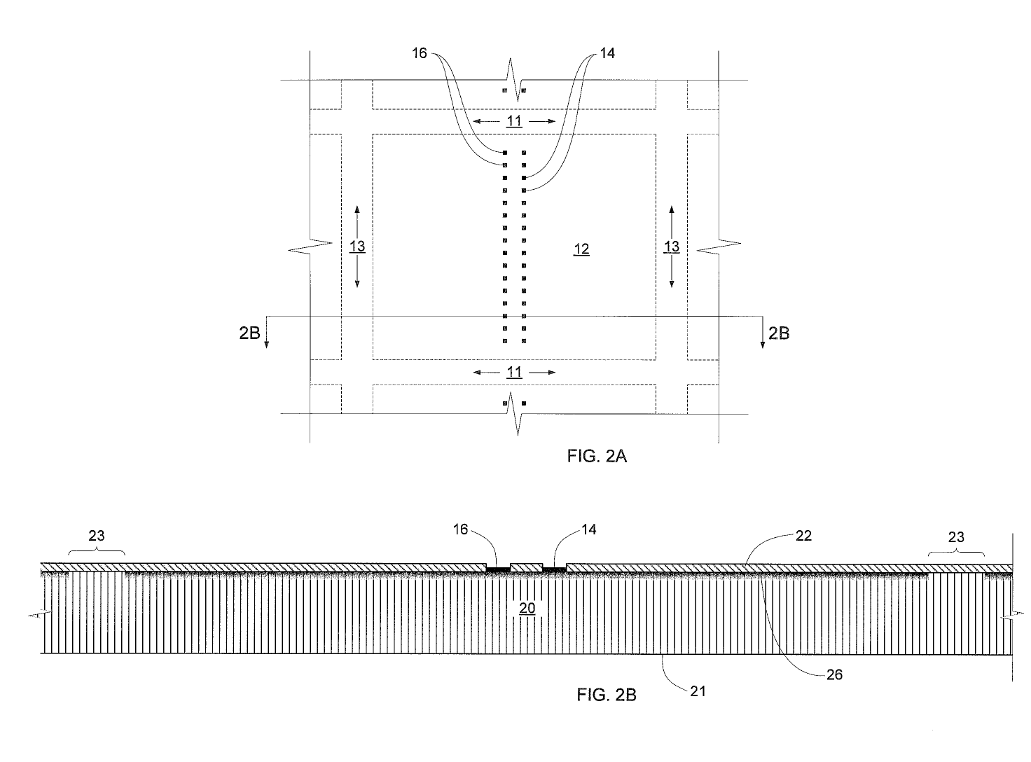

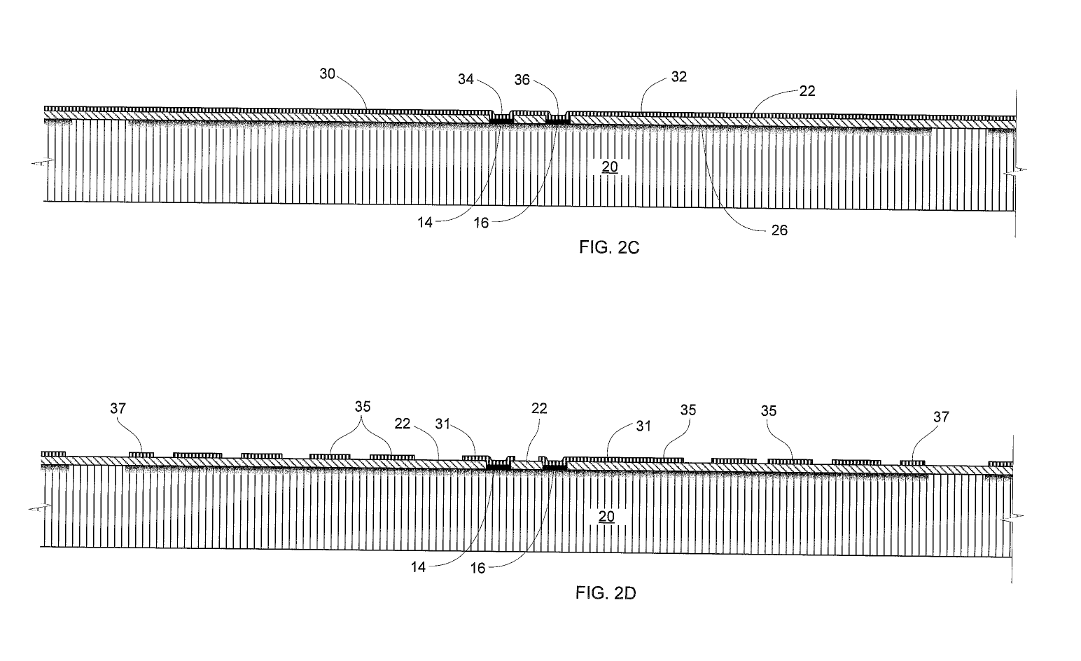

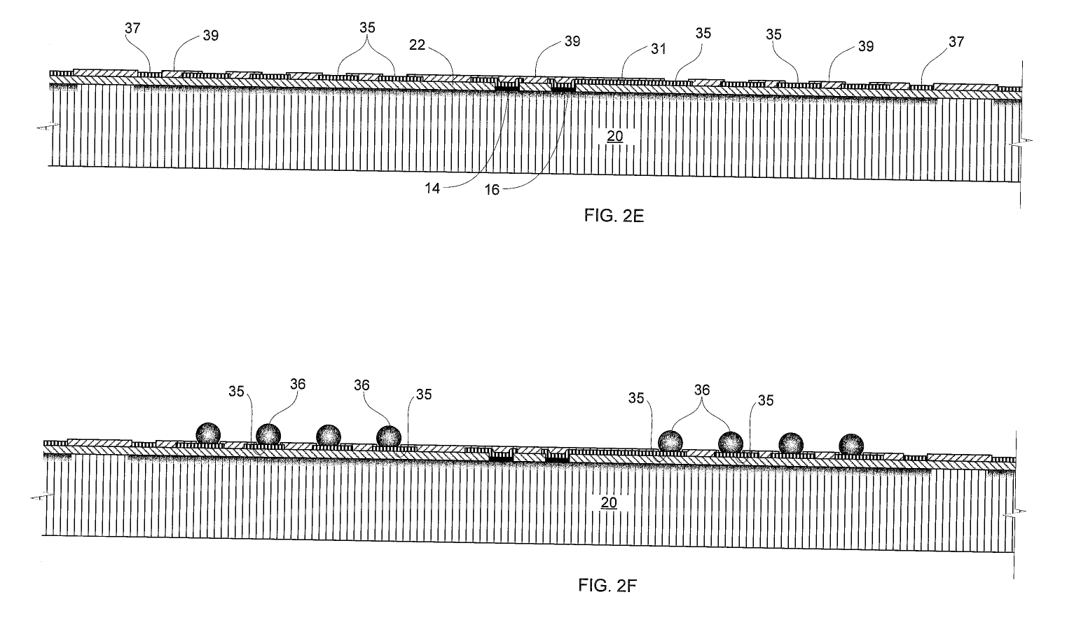

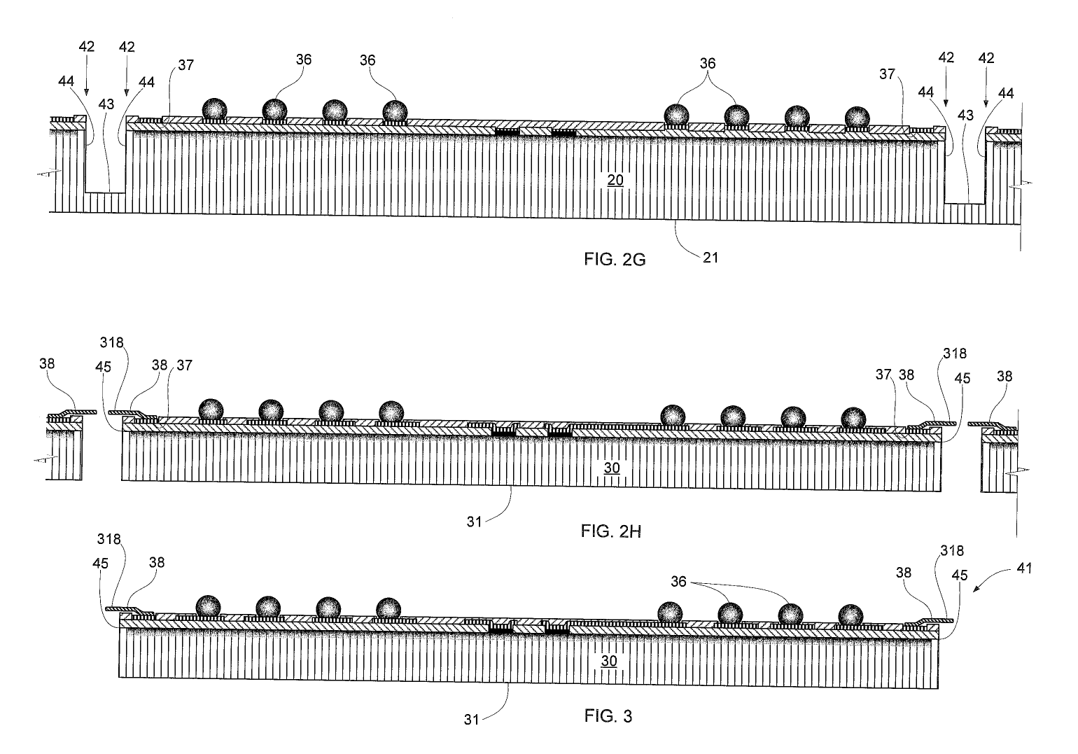

Turning now to FIG. 1A, there is shown in a diagrammatic plan view a half-portion of a semiconductor wafer 10, with the active side in view. A number of integrated circuit chips are formed on the wafer, one of which is indicated at 1B, and shown in greater detail in FIG. 1B. Referring to FIG. 1B, an active region 12 of a chip is shown, bounded by saw streets 11 and 13. Interconnect pads 14, 16 are arrayed in rows alongside a centerline of the active region of the chip 12 and, accordingly, the chips shown by way of example in FIGS. 1A, 1B are center-pad die. FIG. 2A shows a chip as in FIG. 1B, somewhat enlarged; and FIG. 2B shows a sectional view thru a portion of a wafer 20 as indicated at 2B-2B in FIG. 2A. The active region of the chip is indicated in the active side of the wafer at 26, opposite the back side 21 of the wafer 20. A passivation layer 22 overlies the active region. Openings in the passivation layer 22 expose die pads 14, 16. Active regions of the respective die are bounded by saw streets 23, and there may additionally be openings (not shown in these Figures) in the passivation layer 22 exposing the saw streets. The wafer may be thinned at this stage, or later, following further processing (as described below). The wafer may be thinned by supporting the wafer, for example on a backgrinding tape (not shown) applied to the active side, and grinding or polishing away a portion of the backside of the wafer. Whether backgrinding is performed at this stage or later, the wafer may be supported for further processing, for example on a dicing tape (not shown) applied to the back side.

The wafer may be provided as described generally above with reference to FIGS. 1A, 1B. In such case, the wafer as provided is “rerouted” to result in prepared die having a suitable arrangement of second-level interconnect pads situated in an area inwardly from a die edge and, in some embodiments, a suitable arrangement of z-interconnect pads situated near at least one die edge, as illustrated for example in FIGS. 2C through 2E.

Such a rerouting procedure may be carried out generally as follows. Patterned electrically conductive traces and interconnect sites are formed, in the example illustrated in the Figures, by mask-and-etch process on an electrically conductive film. Referring to FIG. 2C, an electrically conductive film 30 is formed at the front side of the wafer as provided, over the surface of the passivation layer 22, as shown for example at 32, and over the die pads 14, 16, as shown for example at 34, 36. Then, with reference to FIG. 2D, in a subsequent step the film 30 is patterned by masking and etching to remove the conductive material, exposing areas of the passivation layer 22 and defining traces, e.g., 31, connecting the die pads, e.g. 14, 16 on the wafer as provided with interconnect sites near the edges of the active region 26 of the chip, as shown for example at 37, and in an area inwardly from the edges of the active region 26 of the chip, as shown for example at 35. As may be appreciated, the traces to most of the sites do not appear in this sectional view.

Alternatively, the traces leading from the die pads to the various sites may be formed by depositing an electrically conductive material directly in the desired pattern by, for example, dispensing from a needle or nozzle, or writing, or printing. Suitable electrically conductive materials include electrically conductive polymers, such as electrically conductive epoxies or electrically conductive inks, for example.

In a subsequent procedure, an electrically insulative layer 39 may optionally be formed over the traces 31 and the exposed areas of the passivation 22 on the front side of the wafer 20, and patterned to expose surfaces of the interconnect sites 35, 37, as shown in FIG. 2E and, optionally (not shown in these Figures), to expose saw streets. The material of the electrically insulative layer may be, for example, a polyimide or a parylene; and the openings may be formed by, for example, photolithography (for polyimide, e.g.) or by, for example, laser ablation (for a parylene, e.g.).

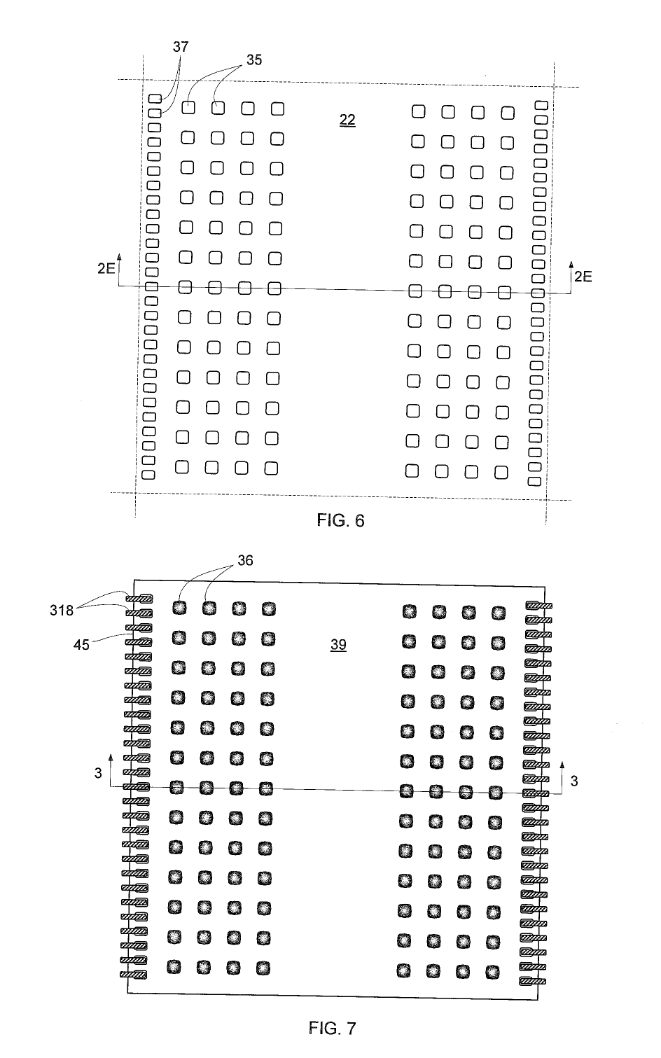

FIG. 6 is a diagrammatic sketch in a plan view showing a stage in a process for making a stackable integrated circuit chip, as shown for example in a diagrammatic sectional view in FIG. 2E, taken at 2E-2E in FIG. 6. As shown, z-interconnect sites 37 are arranged in a row along an edge of the active region and second-level interconnect sites 35 are arranged in an area inboard from the edges; and the sites 37, 35 are exposed for interconnection by openings in the electrically insulative layer 39 (where an electrically insulative layer is present). The wafer may be provided with rerouting circuitry (for example, as a so-called “wafer level chip scale” device), so that as provided the wafer has exposed interconnect sites in an area and/or near the die edges. That is, a wafer as provided may have a configuration as in FIG. 2E for example.

In subsequent procedures, second-level interconnects are attached to interconnect sites situated (and in some embodiments arrayed) in an area inward from edges of the active region (as shown in FIG. 2F); the wafer is scribed along the saw streets to form isolated chip regions, (as shown in FIG. 2G); and the wafer is thinned (as shown in FIG. 2H). Also, in this example, off-die z-interconnect terminals are attached to interconnect sites near the edges of the active region (as shown in FIG. 2H). FIGS. 2F through 2H show a sequence of stages resulting from attaching the interconnect balls, thereafter scribing the wafer, and thereafter thinning the die (resulting in die singulation) and attaching the off-die terminals. Alternatively, these procedures may be carried out in any of various sequences; for example, the wafer may be thinned following scribing, so that die singulation precedes die thinning; and, for example, the second-level interconnect balls may be attached either prior to or following wafer thinning, or prior to or following die singulation; and, for example, the z-interconnect off-die terminals may be attached following die singulation and separation from the die array.

The construct may be tested for electrical performance at any of various stages in the process: on the wafer, on the array of die, or on singulated die. Particularly, for example, testing may be carried out at the wafer level, either on the sites (lands) prior to attachment of second-level interconnects or on the second-level interconnects following attachment (e.g., at a stage shown in FIG. 2F).

FIG. 2F shows second-level interconnects (in this example, balls or bumps 36) formed on or attached to the surfaces of interconnect sites 35. The second-level interconnects may be, for example, solder balls, or “stud bumps” (particularly for example gold stud bumps); or, the second-level interconnects may be spots of electrically-conductive polymer deposited or printed on the interconnect sites, such as an electrically conductive epoxy or an electrically conductive ink, for example.

FIG. 2G shows a result of scribing an unthinned wafer 20 at the active side, to isolate chip regions. Scribing may be carried out by sawing along the saw streets, for example, as shown by arrows 42; or, scribing may be carried out by laser cutting or by etching, for example. Scribing may be carried out to a depth somewhat less than the full thickness of the wafer, as indicated at 43, and results in formation of die sidewalls 44. FIG. 2H shows a scribed wafer thinned by removing material from the wafer back side 21, for example by backgrinding, to form singulated thinned die 30 having back side 31. FIG. 2H additionally shows off-die interconnect terminals 38 attached to interconnect sites 37. The off-die terminal has a portion 318 overhanging the die edge 45.

A singulated die resulting from procedures described above is shown generally at 41 in FIG. 3, ready for stacking with additional die, or for mounting on and electrically connecting to underlying circuitry.

FIG. 7 is a diagrammatic sketch in a plan view showing a stackable integrated circuit chip according to an embodiment of the invention, as shown for example in a diagrammatic sectional view in FIG. 3, taken at 3-3 in FIG. 7. As shown, second-level interconnect balls 36 are attached to the second-level sites 35 and z-interconnect off-die terminals are attached to the row of sites 37, with a portion 318 projecting beyond the die edge 45.

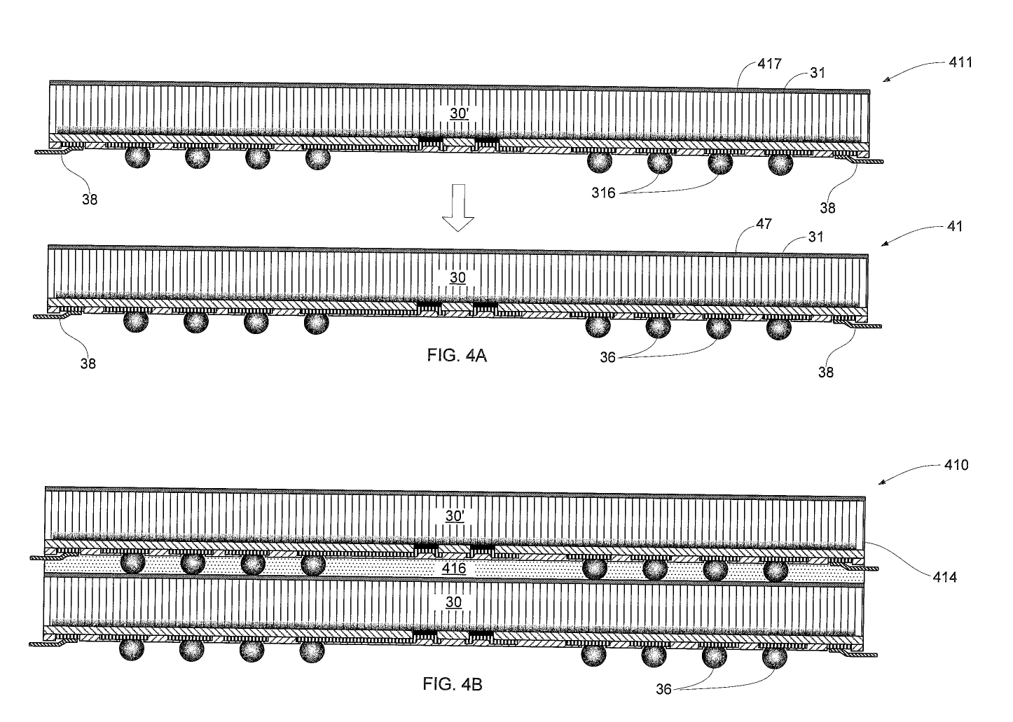

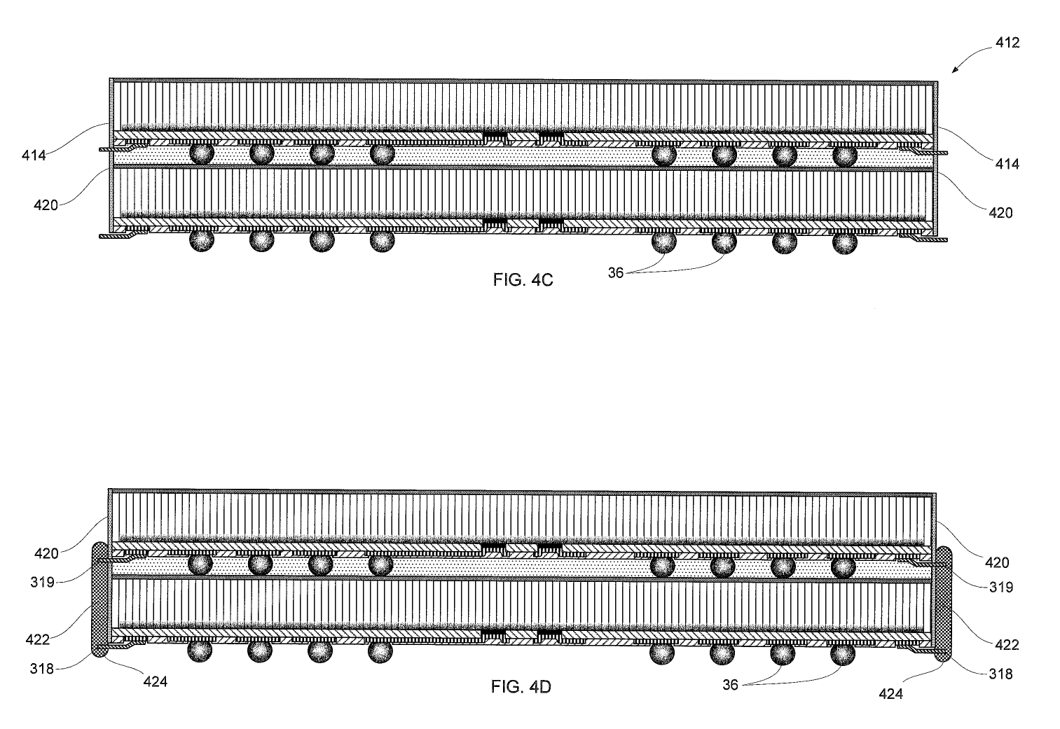

FIG. 4A shows a first die 41, having electrically conductive second-level interconnection balls 36 and off-die z-interconnects 38, and a second die 411, situated for stacking with first die 41. Additional die, not shown in the Figures, may be stacked over the second die, to make a stack having any desired number of die. The second die 411 and additional die may be constructed substantially the same as the first die; that is, the second and additional die may have electrically conductive second-level interconnection balls and off-die z-interconnects. When the second die is so configured, the first die 41 is provided over the back side 31 with an electrically insulative layer 47, to prevent electrical contact of the second-level interconnection balls of the second die with the first die. And where the additional die are so configured, the second die is provided over the back side 31 with an electrically insulative layer 417, to prevent electrical contact of the second-level interconnection balls of the third die with the second die. Alternatively, the second (and additional) die may be provided with standoff balls or bumps 316 formed of an electrically nonconductive material, so that no electrically insulative layer 47 or 417 is required.

FIG. 4B shows two-die stack 410 having first and second die as shown for example in FIG. 4A, mounted with an electrically nonconductive adhesive fill 416 between the adjacent die in the stack. The stack presents stack faces 414, generally planar and generally perpendicular to the front side of the first die. The stack faces include the sidewalls of the stacked die and the sides of the adhesive fill between the die. The off-die interconnect terminals project away from the die edges and from the stack faces 414. Additional die may be stacked over the die 411 similarly to form a stack having any desired number of die.

And, alternatively, the passivation and/or the dielectric layer may be left in place over the front side of the second (and additional) die, so that the sites 35, 37 are not exposed, so that no electrically insulative layer 47 or 417 is required.

Alternatively, circuitry may be formed (in a manner similarly to formation of the rerouting circuitry on the die front side) on the back side of a lower die in a stack, having an arrangement of lands and traces running to interconnect pads near one or more die edges. This may permit electrical contact with electrically conductive interconnects on an overlying die, providing electrical continuity from circuitry on the active side of a die through the arrangement of interconnects to lands on the circuitry on the back side of an underlying die, and through the back side circuitry to back side interconnect pads on the underlying die, and (by contact with peripheral z-interconnects) to other die in the stack or to circuitry underlying the stack assembly. And, alternatively, an interposer having lands and circuitry and peripheral pads may be employed between die in the stack to provide electrical continuity in a similar manner; such an interposer may, for example, consist of a “dummy” die provided with patterned electrically conductive traces and, optionally and for example, with off-die interconnect terminals.

FIG. 4C shows a two-die stack 412, having an electrically insulative layer 420 formed over the stack faces 414. The electrically insulative layer 420 may be formed following stacking, or, alternatively, electrically insulation 420 may be applied to the die sidewalls on the die prior to stacking the die in the assembly. The off-die interconnect terminals project away from the die edges and from the stack faces 414 and the electrically insulative layer 420, where they are available for z-interconnection, as shown in FIG. 4D. The z-interconnects 422 as shown in FIG. 4D contact the respective projecting portions 318, 319 of the off-die terminals. The material of the z-interconnects may be, for example, an electrically conductive polymer such as a curable metal-filled epoxy, for example. The z-interconnects may be formed in contact with the insulative layer 420, as shown by way of example in the FIGS., and thereafter cured. The z-interconnects (or selected ones of them) may optionally each have a projecting “foot” which may provide for electrical connection with sites on underlying circuitry (second-level interconnection), along with the second-level interconnect bumps 36 on the first die.

A die stack as shown in FIG. 4C may be mounted on a support having interconnect pads on appropriately configured circuitry, and electrically connected by bonding the balls 36 and, optionally, the feet 424 to the interconnect pads on the support. The support may be, for example, a printed circuit board such as a motherboard, or daughterboard or the like, in a device for use.

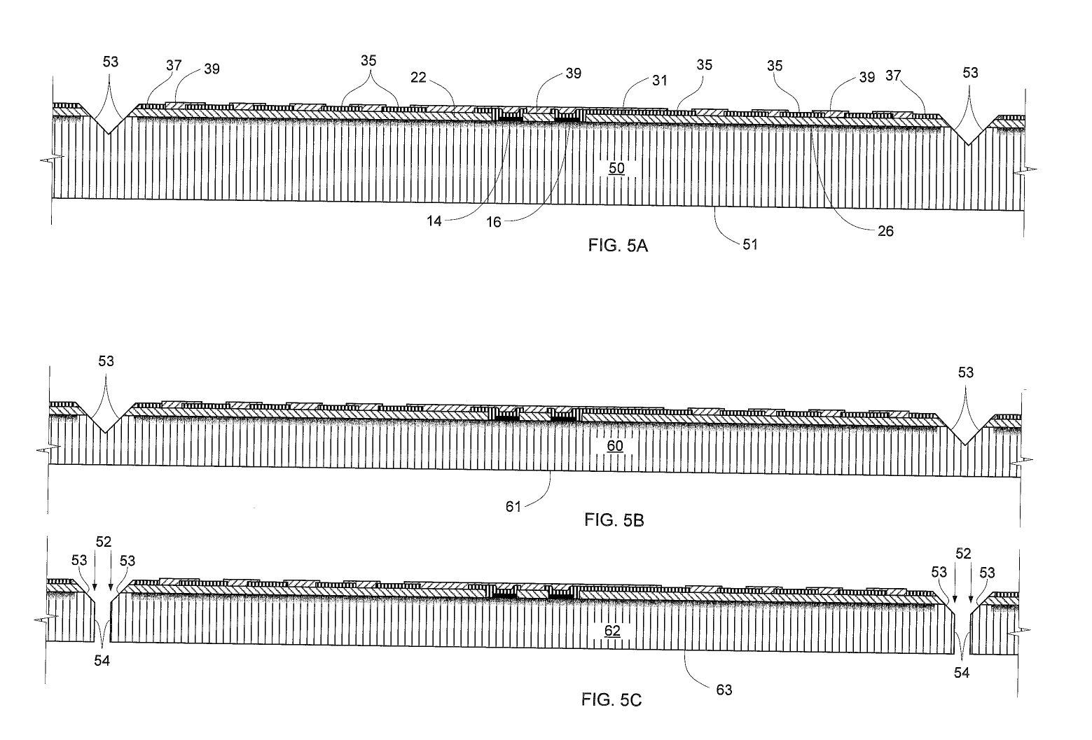

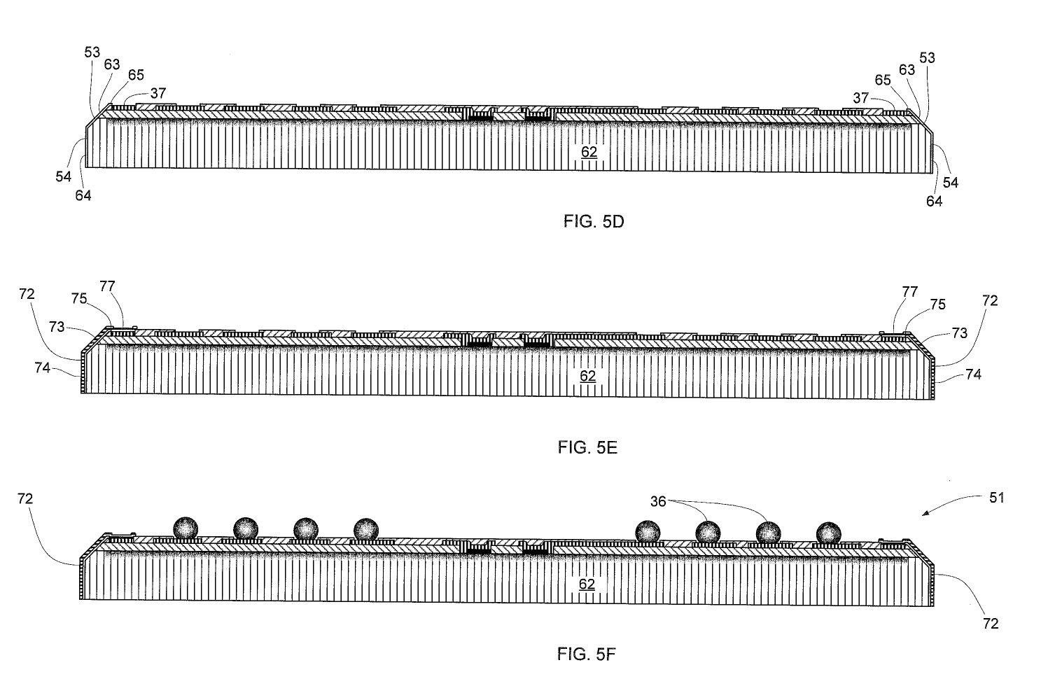

As noted above, z-interconnection other than off-die interconnection may be employed. For example, the terminals may constitute electrically conductive material formed as traces in contact with the various z-interconnect sites and wrapping around the front side die edge and, optionally, onto the die sidewalls. FIGS. 5A-5F show stages in a process for making stackable die having such interconnects, in which the front side die edge is chamfered, and in which the z-interconnect terminal is formed in contact with the z-interconnect site, and over the chamfered edge onto the die sidewall.

The process departs from a stage as shown in FIG. 2E, that is, following rerouting procedures, if necessary, or beginning with a rerouted wafer as provided; and prior to attachment of the second-level interconnect balls, or scribing the wafer, or singulating the die. In subsequent procedures grooves are formed in the saw streets to chamfer the die edges (as shown in FIG. 5A); the wafer is thinned (as shown in FIG. 5B); the wafer is sawn through to form die sidewalls and to singulate the die (as shown in FIG. 5C); a dielectric cap is formed over the chamfered edges and over the sidewalls (as shown in FIG. 5D); z-interconnect traces are formed (as shown in FIG. 5E); and second-level interconnect balls or bumps are attached (as shown in FIG. 5F). FIGS. 5A through 5F show a sequence of stages resulting from chamfering the die edges, thereafter thinning the wafer, thereafter singulating the die, forming the dielectric cap, thereafter forming the z-interconnect traces, and thereafter attaching the second-level balls or bumps. Alternatively, these procedures may be carried out in any of various sequences.

The construct may be tested for electrical performance at any of various stages in the process: on the wafer, on the array of die, or on singulated die. Particularly, for example, testing may be carried out at the wafer level, prior to or following attachment of the second-level interconnects (e.g., at a stage shown in FIG. 5F).

Beginning with a rerouted wafer, grooves are formed in the saw streets, as shown for example in FIG. 5A. The grooves cut at least through the electrically insulative layer 39 (where present) and the passivation layer 22 (where present) and into the semiconductor material 50 of the wafer; the grooves are located so that they are outside the limits of the active regions 26 of the respective chips, so that the grooves do not impact the onboard circuitry of the chips. The grooves have sloped sides 53; that is, they are narrower at the bottom than at the top. In the example shown in the Figures the sides 53 of the grooves are generally planar, and the plane of the grooves is at an angle less than 90° (for example, about 45°) to the plane of the front side of the wafer.

The grooves may be formed by cutting, using for example a saw or grinding tool, or for example using a laser. Where the grooves are cut, more than one pass of the cutting tool may be employed. Or, the grooves may be formed by chemical etching, for example.

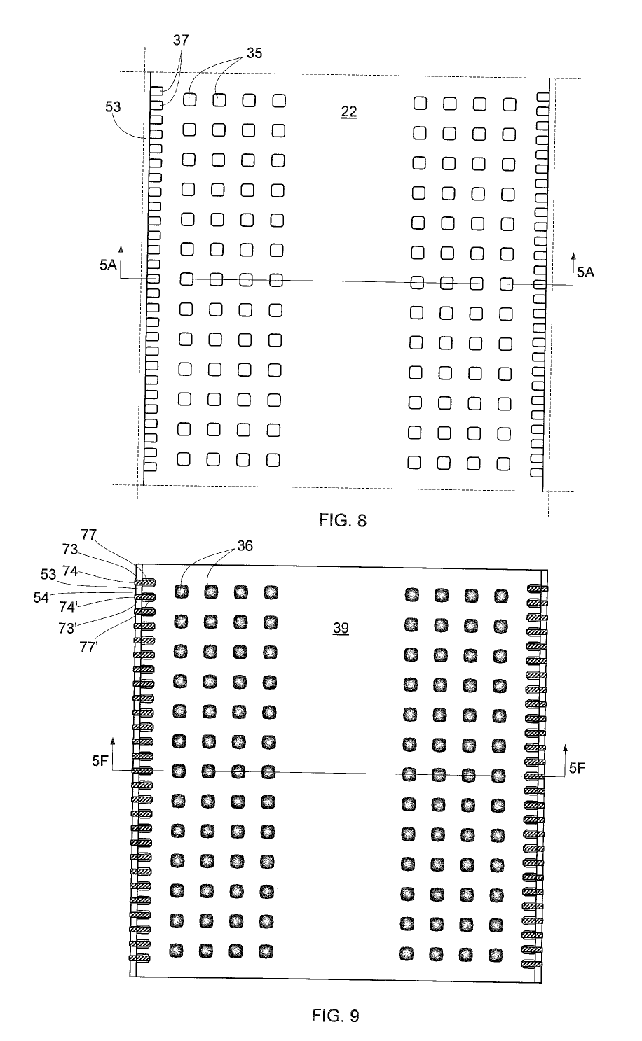

FIG. 8 is a diagrammatic sketch in a plan view showing a stage in a process for making a stackable integrated circuit chip, as shown for example in a diagrammatic sectional view in FIG. 5A, taken at 5A-5A in FIG. 8. As shown, z-interconnect sites 37 are arranged in a row along an edge of the active region and second-level interconnect sites 35 are arranged (in the illustrated example, arrayed) in an area inboard from the edges; and the sites 37, 35 are exposed for interconnection by openings in the passivation layer 22.

If the wafer has not been previously thinned, it may be thinned by removing material from the wafer back side 51, for example by backgrinding, to form a thinned wafer 60 having back side 61, as shown in FIG. 5B. In the example shown in these Figures, the grooves are made to a depth less than the thickness of the thinned wafer. In a procedure following formation of the grooves, the wafer is diced, with a result as shown for example in FIG. 5C. Dicing may be accomplished by cutting, for example using a dicing saw, or a laser, as indicated by arrows 52. The semiconductor body of the resulting die 62 has sidewalls, e.g., 54 (for example) (formed by the dicing procedure), generally perpendicular to the plane of the front side (and back side 63) of the die, and chamfered front die edges, e.g., 53 (formed by the groove formation).

In a subsequent procedure an electrically insulative film is formed over the die sidewalls 54 and the chamfered front die edges 53. The insulative film covers at least the portions of the die semiconductor material over which the z-interconnect traces are subsequently formed (as described below with reference to FIGS. 5E and 9). Accordingly, the electrically insulative film covers the sidewall 54, as shown at 64; the chamfered front die edge 53 as shown at 63, and a portion 65 (if present) of the die front surface exposed between the pad 37 and the chamfered edge 63.

In a procedure thereafter the z-interconnect traces are formed over the electrically insulative film, with a result as shown for example in FIG. 5E. The trace 72 makes electrically conductive contact with the pad 37, as shown at 77; and—separated from the semiconductor material of the die by the insulative film 65, 63, 64—passes over the portion (if present) of the front side of the die between the pad and the chamfered die front edge, over the chamfered die front edge, and over the die sidewall, as shown at 75, 73, 74, respectively. The z-interconnect trace accordingly provides electrical continuity from the pad and around the die edge to the die sidewall.

Second-level interconnects are attached to, or are formed on, second-level interconnect sites, at any of a several stages in the process. In the example shown in the Figures, second-level interconnect balls or bumps 36 are shown attached to the die. A singulated die resulting from procedures described above is shown generally at 51 in FIG. 5F, ready for stacking with additional die, or for mounting on and electrically connecting to underlying circuitry.

FIG. 9 is a diagrammatic sketch in a plan view showing a stackable integrated circuit chip according to an embodiment of the invention, as shown for example in a diagrammatic sectional view in FIG. 5F, taken at 5F-5F in FIG. 9. As shown, second-level interconnect balls 36 are attached to the second-level interconnect sites 35 and z-interconnect traces are connected to the sites 37, as shown for example at 77, 77′, pass over the chamfered edge 53, as shown for example at 73, 73′, and pass onto the die sidewall 54, as shown for example at 74, 74′.

As is apparent in FIG. 9, areas of the chamfer and the sidewall (e.g., 53, 54) between adjacent traces need not be covered by the electrically insulative film. As a practical matter, the film may be formed over the entire chamfer and sidewall rather than selectively, over areas where the z-interconnect traces are to be formed.

Z-interconnection other than off-die interconnection may be employed in die having other configurations. Particularly, for example, the die edge need not be chamfered. In such embodiments the die sidewall is generally perpendicular to the die front side, and the intersection of the sidewall and the front side defines a generally right-angle front die edge. In such embodiments the electrically conductive material of the terminals may be formed as traces in contact with the various z-interconnect sites and passing over the front side die edge and onto the die sidewalls. A process for forming the terminals may be similar to that described above with reference to FIGS. 5A-5F, except that the procedure of forming the grooves to form the chamfer (53 in FIG. 5A, for example) is omitted; and the trenches forming the die sidewalls (54 in FIG. 5C, for example) may be cut prior to backgrinding. The conductive material of the terminals may be formed following backgrinding at the die array level of processing; or, more usually, the conductive material of the terminals may be formed prior to backgrinding at the wafer level of processing. Using a die configuration without chamfered edges can eliminate processing steps, and may be preferred.

The electrically conductive traces making up the terminals may be formed of any of a variety of electrically conductive materials, including metals and metal alloys, conductive inks, and conductive epoxies, for example. The conductive traces may be formed by any of a variety of techniques, selected as appropriate according to the material. Metal traces (gold, aluminum, copper) can be formed by applying a metal film (for example by sputtering or evaporative deposition) or metallization such as a laminate foil, or by sputtering or by plating or by a combination of sputtering and plating, and then pattering in a mask-and-etch process, for example. Electrically conductive fluids (including for example nanoparticle conductive inks) may be printed, for example by screen printing or stencil printing or by deposition from a jet or from an array of jets; or may be applied by direct transfer using a patterned stamp; or may be written, for example. Conductive epoxies or pastes, such as epoxies filled with metal particles (such as gold or silver, for example), may be dispensed, for example. The material for the traces may be a curable material; in such embodiments the curable material may be electrically conductive in the uncured condition, or only when cured, or in both the uncured and the cured condition.

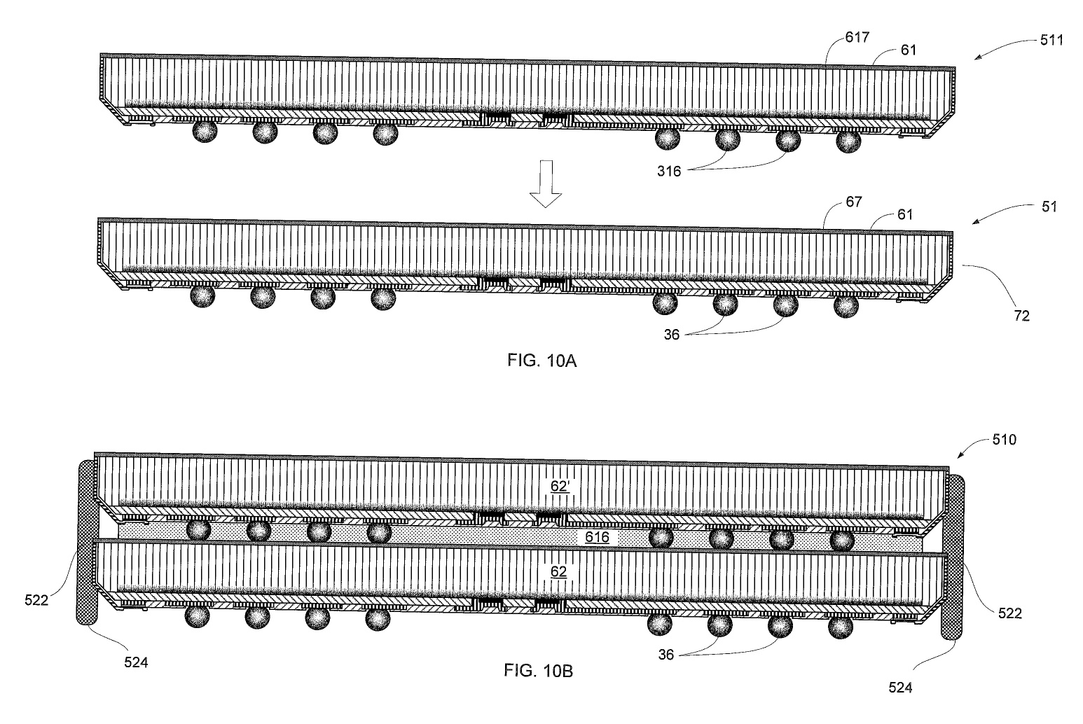

FIG. 10A shows a first die 51, having electrically conductive second-level interconnection balls 36 and z-interconnect traces 72, and a second die 511, situated for stacking with first die 51. Additional die, not shown in the FIGs., may be stacked with the second die. The second die 511 and additional die may be constructed substantially the same as the first die; that is, the second and additional die may have electrically conductive second-level interconnection balls and z-interconnect traces. When the second die is so configured, the first die 51 is provided over the back side 61 with an electrically insulative layer 67, to prevent electrical contact of the second-level interconnection balls of the second die with the first die. And where the additional die are so configured, the second die is provided over the back side 61 with an electrically insulative layer 617, to prevent electrical contact of the second-level interconnection balls of a third die with the second die. Alternatively, the second (and additional) die may be provided with standoff balls or bumps 316 formed of an electrically nonconductive material, so that no electrically insulative layer 67 or 617 is required.

FIG. 10B shows two-die stack 510 having first and second die as shown for example in FIG. 10A, mounted with an electrically nonconductive adhesive fill 616 between the adjacent die in the stack, and electrically interconnected by z-interconnects 522. The stack presents stack faces, generally planar and generally perpendicular to the front side of the first die. The stack faces present the interconnect traces 72 overlying the electrically insulative film at the sidewalls of the stacked die. Additional die may be stacked over the die 511 similarly to form a stack having any desired number of die.

The z-interconnects 522 as shown in FIG. 10B contact the respective z-interconnect terminals at the sidewalls (and, in the examples shown, partly at the chamfered die edges. The material of the z-interconnects may be, for example, a material that is applied in a liquid or flowable form, and thereafter cured or allowed to cure or set, which is electrically conductive when cured or set. Suitable materials include an electrically conductive polymer such as a curable metal-filled epoxy, for example. The z-interconnects may be formed and thereafter cured. The z-interconnects (or selected ones of them) may optionally each have a projecting “foot” 524 which may provide for electrical connection with sites on underlying circuitry (second-level interconnection), along with the second-level interconnect bumps 36 on the first die.

A die stack as shown in FIG. 10B may be mounted on a support having interconnect pads on appropriately configured circuitry, and electrically connected by bonding the balls 36 and, optionally, the feet 524 (where present, as illustrated here) to the interconnect pads on the support. The support may be, for example, a printed circuit board such as a motherboard, or daughterboard or the like, in a device for use.

As noted above, second and subsequent die in the stack may have non-conductive standoffs in place of the second-level interconnects. These may be, for example, balls of a nonconductive material such as a glass or a nonconductive polymer. Where a standoff is present, the amount of the standoff may typically be in a range at least about 1 um and up to about 500 um, such as in a range about 50 um to about 500 um, for example.

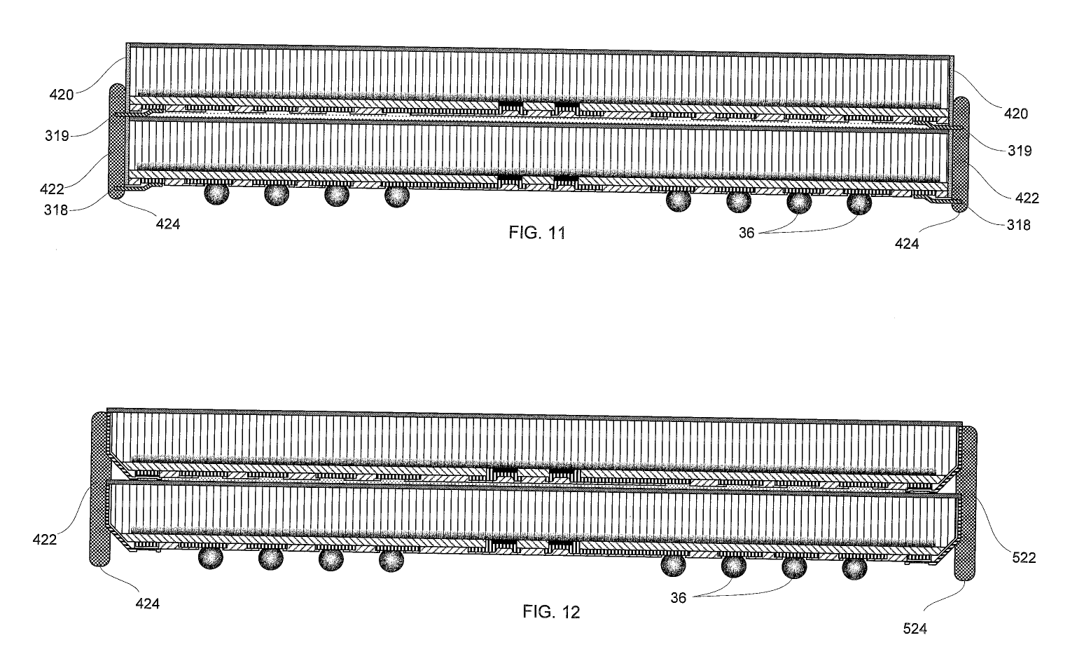

Or, as shown for example in FIGS. 11 and 12, second and subsequent die in the stack may have no standoffs at all, resulting in a thinner stack assembly.

In various embodiments, as noted above, electrical connection of the stacked die assembly to underlying circuitry on an underlying support (for example on a substrate, or a printed circuit board such as a motherboard or daughterboard, or a leadframe, or the like) may be made by way of electrically conductive interconnects situated in the stack footprint between a first die in the stack and the support within the shadow of the stacked die assembly. Additionally, electrical connection of the assembly (or of selected die in the stack) to underlying circuitry may optionally be made by way of “feet” on peripheral z-interconnects. Die-to-die interconnection may be made by peripheral interconnects at one or more stack faces. Additionally, die-to-die interconnection may optionally be made by way of interconnects between die, using die backside circuitry or using an interposer.

As a practical matter, second-level interconnect of the stack of die with underlying circuitry may more usually be made either (and most usually) by way of the interconnects in the shadow of the first die; or (less usually) by both the interconnects in the shadow of the first die and by way of “feet” on peripheral z-interconnects. Wafer level processing in processes as described herein may provide for greatest flexibility at the assembly line; various options may be exercised on various of prepared die in the wafers at various stages in the process.

Other embodiments are contemplated.

We claim:

1. A semiconductor die assembly comprising a second die mounted on a first die, wherein the front side of the second die faces the back side of the first die, and the front side of the first die includes z-interconnect pads situated near at least one die edge, and second-level interconnect pads situated in an area inwardly from a die edge.

2. The assembly of claim 1 wherein both the first and the second die include z-interconnect pads situated near at least one die edge.

3. The assembly of claim 2 wherein interconnect terminals are attached to the z-interconnect pads and project to or beyond the die edge.

4. The assembly of claim 3 wherein the interconnect terminal comprises one selected from the list consisting of a ribbon bond, a tab bond, a deposit of solder paste, a deposit of an electrically conductive polymer, a trace of conductive material formed in contact with the pads and extending to a die edge, a trace of conductive material formed in contact with the pads and around a chamfered or rounded die edge, and a trace of conductive material formed in contact with the pads and extending over a die edge to an adjacent die sidewall.

5. The assembly of claim 1 wherein both the first and the second die include second-level interconnect pads situated in an area inwardly from a die edge.

6. The assembly of claim 1 wherein the first die has electrically conductive second-level interconnect balls attached to second-level interconnect pads.

7. The assembly of claim 1 wherein the second die has standoff balls attached to the second-level interconnect pads.

8. The assembly of claim 7 wherein the material of the standoff balls is electrically conductive.

9. The assembly of claim 7 wherein the first die includes an electrical insulator situated between the back side of the first die and the standoff balls of the second die.

10. The assembly of claim 7 wherein the material of the standoff balls is electrically nonconductive.

11. The assembly of claim 1, further comprising at least one additional die mounted on the second die.

12. A method for preparing semiconductor die, comprising:
providing a semiconductor wafer having electronic circuitry formed in die areas of an active side thereof, and including peripheral z-level interconnect sites situated near at least one die edge and second-level interconnect sites situated in an area inwardly from a die edge.

13. The method of claim 12, further comprising forming standoff bumps on at least selected ones of the second-level interconnect sites.

14. The method of claim 12, further comprising forming interconnect terminals on at least selected ones of the peripheral z-level interconnect sites.

15. The method of claim 13 wherein forming the standoff bumps includes forming bumps of an electrically conductive material on at least selected ones of the sites.

16. The method of claim 15 wherein the electrically conductive material comprises one selected from the group consisting of a stud bump, a solder paste, and a curable electrically conductive material.

17. The method of claim 13 wherein forming the standoff bumps includes forming bumps of an electrically insulative material on at least selected ones of the sites.

18. The method of claim 17 wherein the electrically insulative material comprises one selected from the group consisting of a glass and an organic polymer.

19. The method of claim 17 wherein the bumps have a spheroidal shape.

20. A method for preparing semiconductor die, comprising:
providing a semiconductor wafer having electronic circuitry formed in die areas of an active side thereof, and including a first dielectric layer having openings exposing die pads connected to the electronic circuitry at the surface of the wafer; and
forming electrically conductive rerouting traces over the first dielectric layer, electrically connected to the die pads, the rerouting traces including peripheral z-level interconnect sites situated near at least one die edge and second-level interconnect sites situated in an area inwardly from a die edge.

21. The method of claim 20, further comprising forming standoff bumps on at least selected ones of the second-level interconnect sites.

22. The method of claim 20, further comprising forming interconnect terminals on at least selected ones of the peripheral z-level interconnect sites.

23. The method of claim 20, further comprising forming a second dielectric layer over the rerouting traces.

24. The method of claim 23, further comprising forming openings through the second dielectric layer exposing a plurality of said second-level interconnect sites.

25. The method of claim 23, further comprising forming openings through the second dielectric layer exposing a plurality of said peripheral z-level interconnect sites.

26. The method of claim 25, further comprising forming interconnect terminals on at least selected ones of the peripheral z-level interconnect sites.

27. The method of claim 21 wherein forming the standoff bumps includes forming bumps of an electrically conductive material on at least selected ones of the exposed sites.

28. The method of claim 21 wherein forming the standoff bumps includes forming bumps of an electrically insulative material on at least selected ones of the exposed sites.

29. The method of claim 20, further comprising testing the circuitry on the wafer.

30. The method of claim 24, further comprising testing the circuitry on the wafer following forming openings through the second dielectric layer.

31. The method of claim 21, further comprising testing the circuitry on the wafer following forming the standoff bumps.

32. The method of claim 26, further comprising testing the circuitry on the wafer following forming the interconnect terminals.

33. The method of claim 20, further comprising singulating die from the wafer.

34. The method of claim 24, further comprising singulating die from the wafer following forming openings through the second dielectric layer.

35. The method of claim 21, further comprising singulating die from the wafer following forming the standoff bumps.

36. The method of claim 26, further comprising singulating die from the wafer prior to forming the interconnect terminals.

37. The method of claim 21, further comprising forming a die attach adhesive layer over the second dielectric layer and the standoff bumps.

38. The method of claim 20, further comprising thinning the wafer and forming a die attach adhesive layer over the backside of the thinned wafer.

39. The method of claim 33, further comprising forming a die attach adhesive layer over the backside of the die.

40. A method for making a stacked die semiconductor assembly, comprising providing first and second die prepared as recited in claim 11, and mounting the second die upon the first die.

41. The method of claim 40 wherein the mounting is carried out at a wafer processing stage.

42. The method of claim 40 wherein the mounting is carried out at a die array processing stage.

43. The method of claim 40 wherein the mounting is carried out at a singulated die processing stage.

44. The method of claim 40, further comprising forming interconnect terminals on at least selected ones of the peripheral die pads, and forming z-interconnection of at least selected ones of the interconnect terminals.

45. The method of claim 44, further comprising forming lines of an electrically conductive polymer in contact with interconnect terminals to be connected.

46. The assembly of claim 1, further comprising peripheral interconnects contacting at least selected ones of the z-interconnect pads, forming die-to-die interconnection.

47. The assembly of claim 3, further comprising peripheral interconnects contacting at least selected ones of the interconnect terminals, forming die-to-die interconnection.

48. The assembly of claim 1, mounted on a support having bond sites on circuitry therein, wherein at least a plurality of the second-level interconnet pads are electrically connected to bond sites on the support circuitry.
